(19) United States
(12) Patent Application Publication
(10) Pub. No.: US 2007/0018220 A1
(43) Pub. Date: Jan. 25, 2007

(54) Semiconductor device, gate electrode and method of fabricating the same

(76) Inventors: Chang-won Lee, Gwacheon-si (KR); Byung-hee Kim, Seoul (KR); Woong-hee Sohn, Seoul (KR)

Correspondence Address: HARNESS, DICKEY & PIERCE, P.L.C., P.O. BOX 8910, RESTON, VA, 20195, US

(21) Appl. No.: 11/486,066

(22) Filed: Jul. 14, 2006

(30) Foreign Application Priority Data
Jul. 15, 2005 (KR) 10-2005-0064457

(51) Int. Cl. H01L 29/94

(52) U.S. Cl. 257/296

(57) ABSTRACT

Example embodiments of the present invention provide a semiconductor device, a gate electrode and method of manufacturing the same. Other example embodiments of the present invention provide a gate electrode with a refractory metal layer having decreased sheet resistance and increased reliability, a semiconductor device and a method of manufacturing the same. The gate electrode may be formed of a polysilicon layer, an amorphized metal barrier layer formed on the polysilicon layer and/or a refractory metal layer formed on the amorphized metal barrier layer. The polysilicon layer may have a first conductivity type. The semiconductor device may include a semiconductor substrate, a source region, a drain region, a gate insulation layer and/or the gate electrode described above. The source region and the drain region may be formed in the semiconductor substrate. The source and drain regions may have the first conductivity type. The gate insulation layer may be formed on a channel region between the source region and the drain region. The gate electrode may be formed on the gate insulation layer.

### PRIORITY STATEMENT

This application claims the benefit of priority under 35 U.S.C. § 119 from Korean Patent Application No. 10-2005-0064457, filed on Jul. 15, 2005, in the Korean Intellectual Property Office, the disclosure of which is incorporated herein in its entirety by reference.

### BACKGROUND OF THE INVENTION

1. Field of the Invention

Example embodiments of the present invention relate to a semiconductor device, a gate electrode and method of manufacturing the same. Other example embodiments of the present invention relate to a semiconductor device including a gate electrode with a refractory metal layer having decreased sheet resistance and/or increased reliability and a method of manufacturing the same.

2. Description of the Related Art

As semiconductor devices become more highly integrated, semiconductor design rules decrease to the submicron range (100 rnm) or finer. As a result, interconnect resistance capacitance (RC) delay becomes a problem. In an effort to circumvent RC delay problems in interconnects, refractory metals may be used as materials for interconnects.

Problems may still occur when using refractory metals as interconnect materials. For example, when a gate line (e.g., a type of interconnect) is formed of a single refractory metal layer, gate insulation layer contamination may occur. Accordingly, the gate line may have a double layer structure formed of an impurity-doped polysilicon layer functioning as a buffer gate line and a refractory layer functioning as a main gate line.

While the double layer structure may circumvent the gate insulation layer contamination problem, other problems may occur. For example, if the refractory metal layer is formed directly on the polysilicon layer, the contact resistance of the refractory metal layer may increase and/or a barrier layer may be formed between the polysilicon layer and the refractory metal layer due to a silicide reaction between silicon components of the polysilicon layer and metal components of the refractory metal layer. The barrier layer has a crystalline structure. As a result, semiconductor device characteristics may deteriorate.

### SUMMARY OF THE INVENTION

Example embodiments of the present invention relate to a semiconductor device, a gate electrode and method of manufacturing the same. Other example embodiments of the present invention relate to a gate electrode with a refractory metal layer having decreased sheet resistance and increased reliability, a semiconductor device and a method of manufacturing the same.

According to example embodiments of the present invention, there is provided a semiconductor device including a first conductivity type transistor. The first conductivity type transistor may include a semiconductor substrate, a source region, a drain region, a gate insulation layer and/or a gate electrode. The source region and/or drain region may have a first conductivity type. The source region and/or drain region may be formed in the semiconductor substrate. The gate insulation layer may be formed on a channel region between the source region and the drain region. The gate electrode may include a polysilicon layer, a metal barrier layer and/or a refractory metal layer. The polysilicon layer may be formed on the gate insulation layer. The polysilicon layer may be doped with impurities having the first conductivity type. The metal barrier layer may have an amorphized upper surface. In other words, atoms of the upper surface may be positioned in short-range order. The refractory metal layer may be formed on the amorphized surface of the metal barrier layer. The refractory metal layer may be formed of a metal having a higher melting point than about 1539° C. (e.g., a melting point higher than iron).

According to other example embodiments of the present invention, there is provided a gate electrode including a polysilicon layer having a conductivity type, a metal barrier layer partially amorphized and/or a refractory metal layer.

According to other example embodiments of the present invention, there is provided a method of fabricating a semiconductor device including preparing a semiconductor substrate provided with a gate insulation layer thereon, forming a polysilicon layer doped with impurities having a first conductivity type on the gate insulation layer, forming a metal barrier layer on the polysilicon layer, amorphizing the surface of the metal barrier layer, forming a refractory metal layer on the amorphized surface of the metal barrier layer and/or forming a gate electrode for a first conductivity type transistor. The gate electrode may be formed by sequentially patterning the refractory metal layer, the metal barrier layer with the amorphized surface, the polysilicon layer doped with the first conductivity type impurities and/or the gate insulation layer.

### BRIEF DESCRIPTION OF THE DRAWINGS

Example embodiments of the present invention will be more clearly understood form the following detailed description taken in conjunction with the accompanying drawings. FIGS. 1-11 represent non-limiting, example embodiments of the present invention as described herein.

FIG. 1 is a cross-sectional view illustrating a semiconductor device including a planar-channel transistor according to an example embodiment of the present invention;

FIG. 2 is a cross-sectional view illustrating a semiconductor device including a recess-channel transistor according to another example embodiment of the present invention;

FIG. 3 is a flow chart for explaining a method of fabricating a semiconductor device according to an example embodiment of the present invention; and

FIGS. 4 through 11 are sequential sectional views illustrating a method of fabricating a semiconductor device including a planar-channel transistor shown in FIG. 1.

### DETAILED DESCRIPTION OF EXAMPLE EMBODIMENTS

Advantages and features of the present invention and methods of accomplishing the same may be understood more readily by referring to the following detailed description of preferred embodiments and the accompanying drawings. The present invention may, however, be embodied in many different forms and should not be construed as being limited to the example embodiments set forth herein. Rather, these embodiments are provided so that this disclosure will be thorough and complete and will fully convey the concept of the invention to those skilled in the art, and the present invention will only be defined by the appended claims. Thus, in some example embodiments, well known methods, procedures, components, and circuits have not been described in detail so as not to unnecessarily obscure embodiments of the present invention.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments of the present invention.

Spatially relative terms, such as “beneath”, “below”, “lower”, “above”, “upper” and the like, may be used herein for ease of description to describe one element or a feature's relationship to another element or feature as illustrated in the Figures. It will be understood that the spatially relative terms are intended to encompass different orientations of the device in use or operation in addition to the orientation depicted in the Figures. For example, if the device in the Figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments of the present invention are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments of the invention should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope of the present invention.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments of the present invention belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments of the present invention, various aspects of the present invention will be described in detail with reference to the attached drawings. However, the present invention is not limited to the example embodiments described.

Moreover, the term “first conductivity type” or “second conductivity type” indicates opposite conductivity type such as P-type or N-type and each embodiment described and illustrated herein includes its complementary embodiment as well.

Hereinafter, a semiconductor device, a gate electrode and a method of fabricating the semiconductor device according to example embodiments of the present invention will be described with reference to the accompanying drawings.

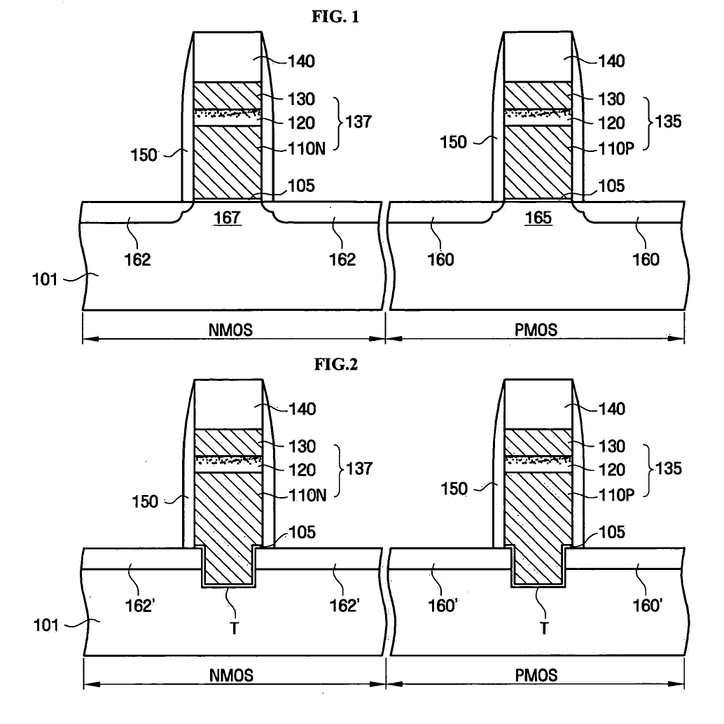

FIG. 1 is a cross-sectional view illustrating a semiconductor device including a planar-channel transistor according to an example embodiment of the present invention.

Referring to FIG. 1, a semiconductor device according to an example embodiment of the present invention may include a first conductivity type transistor. The first conductivity type may be a P-type or a N-type. For example, if the first conductivity is a P-type, a P-type transistor may include P-type source/drain regions 160, a gate insulation layer 105 and/or a gate electrode 135. The P-type source/drain regions 160 may be formed in a semiconductor substrate 101. The gate insulation layer 105 may be formed on a channel region 165 between the P-type source/drain regions 160. The gate electrode 135 may be formed on the gate insulation layer 105. The gate electrode 135 may have a multi-layer structure in which a P-type doped polysilicon layer 110P and a refractory metal layer 130 may be sequentially stacked. The gate electrode 135 may include a metal barrier layer 120 between the polysilicon layer 110P and the refractory metal layer 130. The metal barrier layer 120 may have an upper surface with an amorphous structure.

The amorphous structure of the upper surface of the metal barrier layer 120 may be capable of increasing the size of grains in the refractory metal layer 130 and/or decreasing the sheet resistance of the refractory metal layer 130. The amorphous structure of the barrier layer 120 may extend from the surface of the metal barrier layer 120 to a desired depth into the metal barrier layer 120. Thus, the metal barrier layer 120 may have an amorphous portion which includes the upper surface of the metal barrier layer 120. The amorphous portion of the barrier layer 120 may extend such that a thickness (depth) of the amorphous portion in the metal barrier layer 120 may be less than about 50% of the total thickness of the metal barrier layer 120. If the thickness is greater than about 50% or a portion of the metal barrier layer 120 is in an amorphous state, then the amorphous portion in the metal barrier layer 120 may increase contact resistance between the refractory metal layer 130 and the polysilicon layers 110P.

The metal barrier layer 120 may be formed of a material such as metal nitride. The metal nitride may include binary compounds or ternary compounds. Examples of binary compounds include tungsten nitride (WNₓ), titanium nitride (TiNₓ), tantalum nitride (TaNₓ). Examples of ternary compounds include tungsten silicon nitride, titanium silicon nitride and tantalum silicon nitride. The examples provided are not limiting.

The refractory metal layer may be formed of a metal having a higher melting point than about 1539° C (e.g., a melting point higher than iron). The refractory metal layer 130 may be formed of a metal selected from the group consisting of tungsten (W), rhenium (Re), tantalum (Ta), Osmium (Os), molybdenum (Mo), Niobium (Nb), vanadium (V), Hafnium (Hf), zirconium (Zr), and titanium (Ti). Other metals, or materials, may also be used as would be appreciated by one in the art.

In other example embodiments of the present invention, tungsten may be used as a material for forming the refractory metal layer 130 in a semiconductor device fabrication process. However, any other materials may be used for the refractory metal layer 130 so long as they are suitably used within the scope of the example embodiments of the present invention.

The P-type doped polysilicon layer l OP formed under the metal barrier layer 120 may be formed of a polysilicon layer doped with only P-type impurities. Alternatively, the P-type doped polysilicon layer 110P may be formed of a polysilicon layer doped with both P-type impurities and N-type impurities, where the concentration of the P-type impurities is higher than the concentration of the N-type impurities.

The gate electrode 135 may include other interlayers (not shown) (such as an anti-diffusion layer and/or an ohmic contact layer) in addition to the doped polysilicon layer 110P and the metal barrier layer 120 described above.

The semiconductor device including the first conductivity type transistor shown in FIG. 1 may also include a second conductivity type transistor.

If the second conductivity type is an N-type, then an N-type transistor (NMOS transistor) may include N-type source/drain regions 162, a gate insulation layer 105 and/or a gate electrode 137. The N-type source/drain regions 162 may be formed in the semiconductor substrate 101. The gate insulation layer 105 may be formed on a channel region between the N-type source/drain regions 162. The gate electrode 137 may be formed on the gate insulation layer 105. The gate electrode 137 may be a multilayer structure in which an N-type doped polysilicon layer 110N and a refractory metal layer 130 may be sequentially stacked. The multilayer structure may include a metal barrier layer 120 having an upper surface with an amorphous structure between the refractory metal layer 130 and the polysilicon layer 110N.

The metal barrier layer 120 and the refractory metal layer 130 in this N-type transistor may be similar to the P-type transistor shown in FIG. 1, therefore an explanation thereof will be omitted for the sake of brevity.

The semiconductor device may have a dual polysilicon gate structure having gate electrodes 135 and 137 formed of polysilicon layers, 110P and 110N, respectively. The polysilicon layers may be doped with different conductivity-type impurities. For example, the P-type (PMOS) transistor may include the gate electrode 135 formed of the polysilicon layer 110P doped with N-type impurities and the N-type (NMOS) transistor may include the gate electrode 137 formed of the polysilicon layer 110N doped with P-type impurities. In order to simplify the fabrication process, a polysilicon layer doped with N-type impurities may be used as a gate electrode for a PMOS transistor. If a gate electrode for a PMOS transistor is formed of a polysilicon layer doped with P-type impurities, then a threshold voltage may be lowered. Accordingly, the dual polysilicon gate structure having the polysilicon layers 110P and 110N may increase the characteristics of transistors.

According to example embodiments of present invention, the polysilicon layer 110P (doped with P-type impurities) may be a polysilicon layer doped with a higher concentration of P-type impurities and a lower concentration of N-type impurities. The polysilicon layer 110N (doped with N-type impurities) may be a polysilicon layer doped with only N-type impurities. According to example embodiments of the present invention, it may easier to fabricate the polysilicon gate structure described above compared to a polysilicon gate structure with a P-type polysilicon layer 110P doped with only P-type impurities and a N-type polysilicon layer 110N doped with only N-type impurities.

Reference numeral 140 denotes a hard mask used for forming the gate electrodes 135 and 137 and reference numeral 150 denotes a spacer.

FIG. 2 illustrates a semiconductor device including a recessed channel transistor according to an example embodiment of the present invention.

As shown in FIG. 2, a channel region for a PMOS transistor between P-type source/drain regions 160′ and a channel region for an NMOS transistor between an N-type source region 162′ and an N-type drain region 162′ may be formed along the surfaces of trenches T recessed in a semiconductor substrate 101. Although the design rule of a gate line may decrease, it may be possible to form a longer channel length. Other elements of the semiconductor device shown in FIG. 2 are similar to the elements in the semiconductor device shown in FIG. 1, therefore a description will be omitted for the sake of brevity.

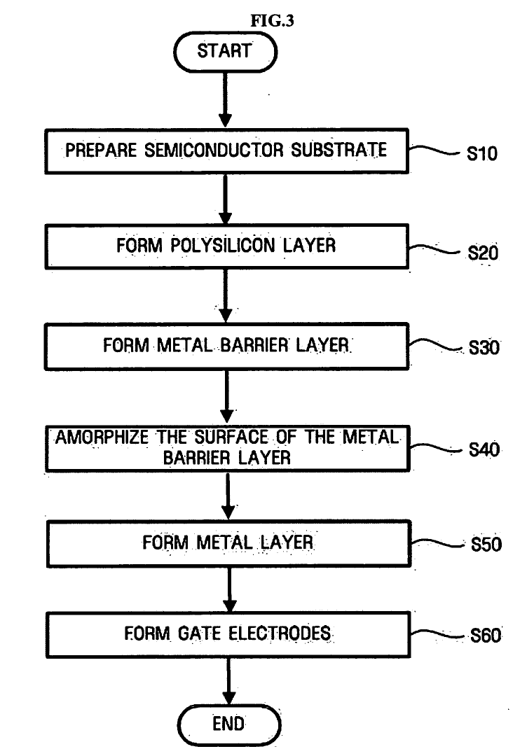

Referring to FIGS. 3 through 11, a fabrication method of the semiconductor device shown in FIG. 1 will be described. In the following description, well-known methods and procedures will be briefly described without detail in order not to obscure example embodiments of the present invention.

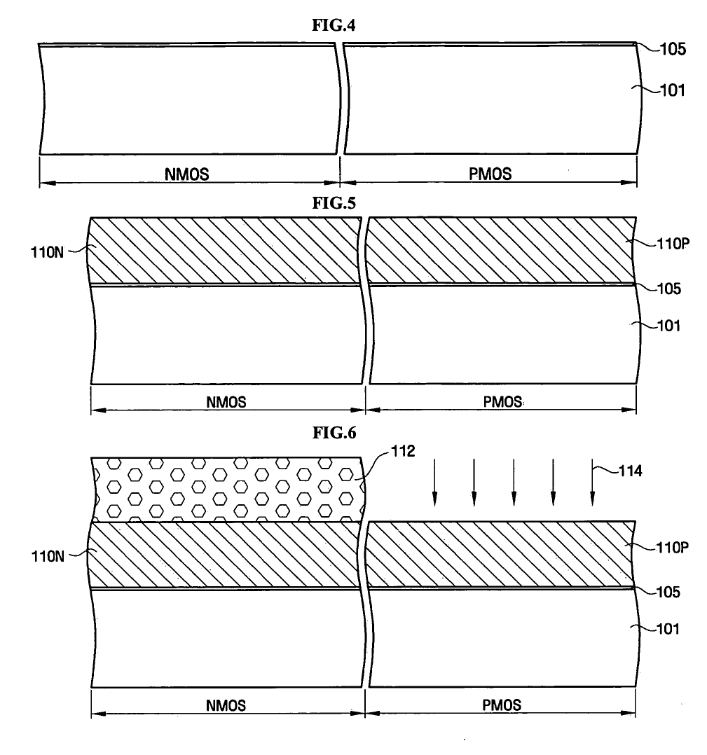

FIG. 3 is a flow chart for explaining a method of fabricating a gate electrode according to an example embodiment of the present invention, and FIGS. 4 to 11 are cross-sectional views illustrating intermediate structures in the fabrication method.

A semiconductor substrate is prepared (S10). Referring to FIG. 4, a device isolation region (not shown) may be formed in the semiconductor substrate to define an active area. A gate insulation layer 105 may be formed on the semiconductor substrate 101.

The semiconductor substrate 101 may be formed of a semiconductor material selected from the group consisting of Si, Ge, SiGe, GaP, GaAs, SiC, SiGeC, InAs and InP. The semiconductor substrate 101 may be, for example, a silicon on insulator (SOI) substrate.

The gate insulation layer 105 may be formed of a silicon oxide layer. The silicon oxide layer may be formed by thermally oxidizing the surface of the semiconductor substrate 101, a silicon oxide nitride layer SiON, a GeₓO_{y}N_{z} layer, a GeₓSi_{y}O_{z} layer, a high dielectric layer, a combination layer thereof or a multilayer structure. The multilayer structure may be formed by sequentially stacking one or more of these layers. The high dielectric layer may be formed of a material selected from the group consisting of HfO₂, ZrO₂, Al₂O₃, Ta₂O₅, hafnium silicate, zirconium silicate and a mixture thereof.

A polysilicon layer may be formed on the gate insulation layer (S20). Referring to FIG. 5, S20 will now be described in more detail. The N-type doped polysilicon layer 110N may be formed on the gate insulation layer 105. The polysilicon layer 110N doped with N-type impurities may be formed by forming a polysilicon layer and sequentially doping the polysilicon layer with N-type impurities by ion implantation. Alternatively, the polysilicon layer 110N doped with N-type impurities may be formed by in-situ doping using N-type impurities, while depositing a polysilicon layer. Examples of the N-type impurities include phosphorous P, arsenic (As) and the like.

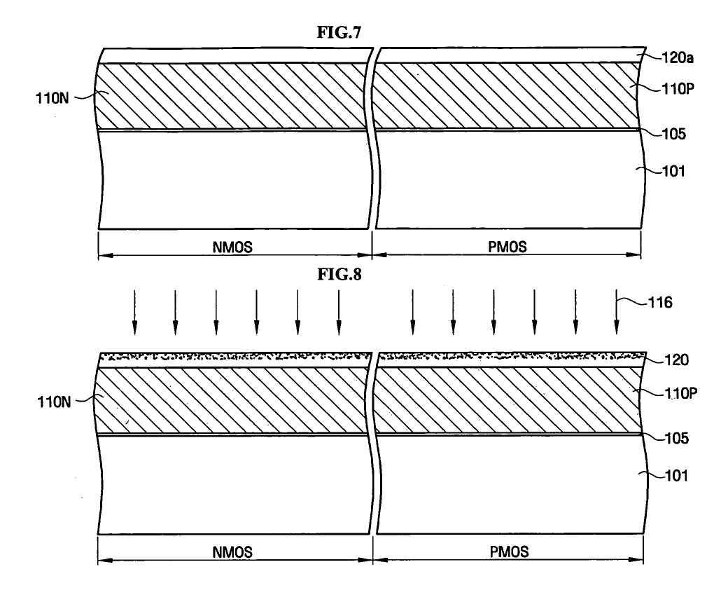

Referring to FIG. 6, a photoresist pattern 112 may be formed to cover active areas wherein NMOS transistors will be formed. P-type impurities may be introduced into the polysilicon layer by an ion implantation method using the photoresist pattern 112 as an ion implantation mask, forming a P-type doped polysilicon layer 110P. Examples of P-type impurities include boron (B), boron fluoride (BF₂) and indium (In).

The process conditions may be such that the dominant conductivity type is P-type conductivity, by implanting P-type impurities with a higher concentration than a concentration of N-type impurities that have been previously implanted in the polysilicon layer.

As shown in FIG. 6, a dual polysilicon gate structure including the N-type doped polysilicon layer 110N and the P-type doped polysilicon layer 110P may be formed on the semiconductor substrate 101. The dual polysilicon gate structure may be formed by implanting N-type impurities and P-type impurities into an NMOS transistor area and a PMOS transistor area, respectively. Two ion implantation masks may be used wherein one ion implantation mask exposes only an NMOS transistor area and the other ion implantation mask exposes only a PMOS transistor area, respectively.

According to example embodiments of the present invention, the method described above with reference to FIGS. 5 and 6, using one ion implantation mask may be require less equipment than the method using two ion implantation masks, decreasing fabrication cost of a semiconductor device.

A rapid nitrification treatment and washing may be performed. A metal barrier layer may be formed on the polysilicon layer (S30). Referring to FIG. 7, metal barrier layer 120a may be formed on the N-type doped polysilicon layer 110N and the P-type doped polysilicon layer 110P. The metal barrier layer 120a may be formed of a metal nitride, as described above.

Surfaces of the metal barrier layers 120a may be amorphized (S40). Referring to FIG. 8, metal barrier layers 120 with the amorphized surfaces may be formed by amorphization, a process wherein atoms of the upper surface may be positioned in short-range order (116). The amorphization may be performed by plasma processing. Plasma sources for the plasma processing may include He, Ne, Ar, Kr, Xe, N₂ or a mixture thereof. The plasma source is not limited thereto. The plasma processing may be performed in a temperature-controllable chamber. The temperature of the chamber may be between room temperature and 900° C. The pressure of the chamber may be 10 Torr or lower.

The amorphized surfaces of the metal barrier layers 120, formed by the plasma processing, may contact a refractory metal layer. The amorphization may progress to a desired, or predetermined, depth into the metal barrier layers from the surface thereof. In other words, an amorphous portion may be formed in each metal barrier layer extending from the surface to the desired depth. If the amorphization progresses beyond the desired depth of the metal barrier layers (e.g., a substantial portion of the thickness of the metal barrier layers is transformed into an amorphous state), the amorphous structure in the metal barrier layers may increase contact resistance of a resulting gate electrode. Accordingly, the thickness of the amorphous structure layer in the metal barrier layers may be about 50% or less of the total thickness of the metal barrier layers.

A refractory metal layer may be formed on the metal barrier layers with the amorphized surface (S50). Referring to FIG. 9, a refractory metal layer 130 may be formed on the metal barrier layers 120 with the amorphized surface. A hard mask 140 may be formed on the refractory metal layer 130 to define gate electrodes. The refractory metal layer 130 may be formed of a metal selected from the group consisting of tungsten (W), rhenium (Re), tantalum (Ta), Osmium (Os), molybdenum (Mo), Niobium (Nb), vanadium (V), Hafnium (Hf), zirconium (Zr) and titanium (Ti), as described above. The hard mask 140 may be formed of a silicon nitride layer.

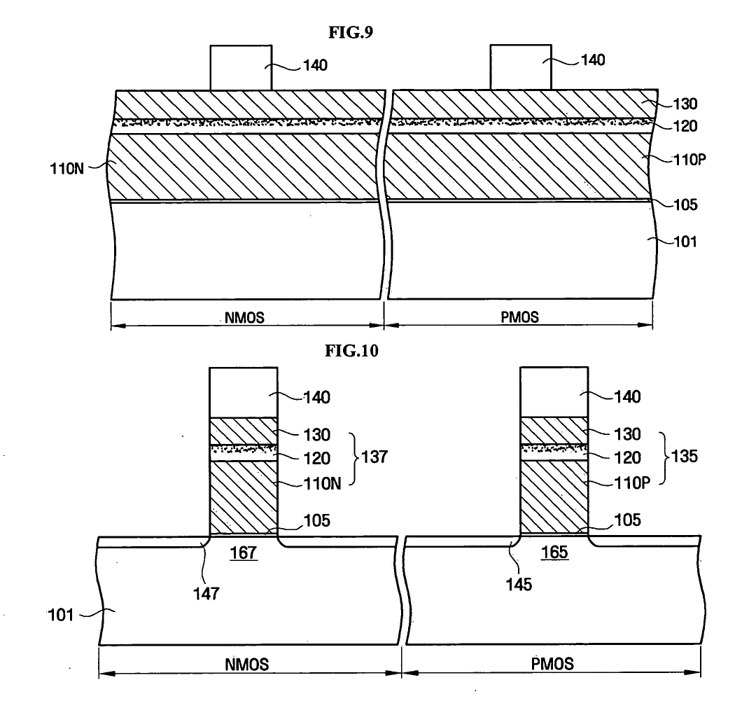

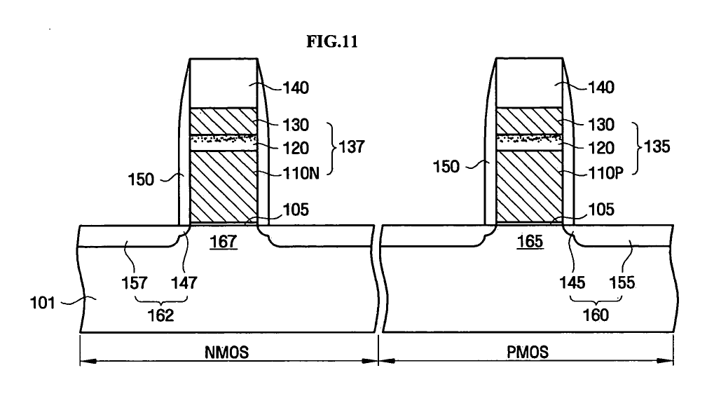

The refractory metal layer 130, the metal barrier layer 120, the polysilicon layers 110N and 110P and the gate insulation layer 105 may be sequentially patterned to form gate electrodes (S60). Referring to FIG. 10, the refractory metal layer 130, the metal barrier layer 120, the polysilicon layers 110N and 110P, and the gate insulation layer 105 may be sequentially etched using the hard mask 140 as an etching mask, forming a gate electrode 135 for a PMOS transistor and a gate electrode 137 for an NMOS transistor.

P-type impurities and N-type impurities may be implanted in the semiconductor substrate 101 in areas such as the PMOS transistor area and the NMOS transistor area, respectively, forming lightly doped P-type source/drain regions 145 and lightly doped N-type source/drain regions 147, respectively.

Referring to FIG. 11, spacers 150 may be formed on sidewalls of the respective gate electrodes 135 and 137. The P-type impurities and the N-type impurities may be implanted into the semiconductor substrate 101 in the areas such as the PMOS transistor area and the NMOS transistor area, respectively, forming highly doped P-type source/drain regions 155 and highly doped N-type source/drain regions 157. As a result, a planar-channel PMOS transistor having a P-type source/drain region 160 and a planar-channel NMOS transistor having an N-type source/drain region 162 may be formed.

Processes well-known to those skilled in the art may be performed. For example, forming interconnects such that electrical signals may be input to and output from the PMOS transistor and the NMOS transistor, forming a passivation layer on the final structure on the semiconductor substrate and/or packaging the semiconductor substrate may be performed, completing fabrication of a semiconductor device. These procedures have not been described in detail to avoid obscuring example embodiments of the present invention.

According to the semiconductor device, the gate electrode and the fabrication method thereof, an upper surface of a metal barrier layer may be amorphized and a refractory metal layer may be formed on the amorphized surface of the metal barrier layer such that the sheet resistance of the refractory metal layer functioning as an interconnect may decrease and/or reliability of the semiconductor device may increase.

In concluding the detailed description, those skilled in the art will appreciate that many variations and modifications can be made to the example embodiments without substantially departing from the spirit and scope of the present invention. Therefore, the disclosed example embodiments of the invention are used in a generic and descriptive sense only and not for purposes of limitation. The present invention is defined by the following claims, with equivalents of the claims to be included therein.

What is claimed is:

1. A gate electrode comprising:
a first polysilicon layer having a first conductivity type,
a first amorphized metal barrier layer on the first polysilicon layer; and
a first refractory metal layer on the first amorphized metal barrier layer.

2. The gate electrode of claim 1, wherein the first polysilicon layer is doped with a higher concentration of P-type impurities than a concentration of N-type impurities.

3. The semiconductor device of claim 2, wherein the first conductivity type is a P-type conductivity.

4. The gate electrode of claim 1, wherein the first amorphized metal barrier layer is a metal nitride layer.

5. The gate electrode of claim 1, wherein the first refractory metal layer is made of a material selected from the group consisting of tungsten nitride (WNx), titanium nitride (TiNx), tantalum nitride (TaNx), tungsten silicon nitride, titanium silicon nitride and tantalum silicon nitride.

6. The gate electrode of claim 1, wherein the first refractory metal layer includes at least one metal selected from the group consisting of tungsten (W), rhenium (Re), tantalum (Ta), Osmium (Os), molybdenum (Mo), Niobium (Nb), vanadium (V), Hafnium (Hf), zirconium (Zr) and titanium (Ti).

7. The gate electrode of claim 1, wherein the first amorphized metal barrier layer has an amorphous structure portion at an upper part thereof, wherein the amorphous structure portion extends from a surface of the first amorphized metal barrier layer to a depth into the first amorphized metal barrier layer, further wherein a thickness of the amorphous structure portion is 50% or less of a total thickness of the first amorphized metal barrier layer.

8. The gate electrode of claim 7, wherein the first polysilicon layer has a N-type conductivity, the first polysilicon layer being doped with a higher concentration of N-type impurities than a concentration of P-type impurities.

9. The gate electrode of claim 8, wherein the first conductivity type is a N-type conductivity.

10. A semiconductor device including a first conductivity type transistor, comprising:
a semiconductor substrate;
a first source region and a first drain region, wherein the first source region and the first drain region are formed in the semiconductor substrate and having the first conductivity type;
a first gate insulation layer formed on a first channel region between the first source region and the first drain region; and
the gate electrode according to claim 1 formed on the first gate insulation layer wherein the gate electrode is a first gate electrode.

11. The semiconductor device of claim 10, further comprising a second conductivity type transistor including:
a second source region and a second drain region wherein the second source region and the second drain region are formed in the semiconductor substrate and having a second conductivity type;
a second gate insulation layer formed on a second channel region between the second source region and the second drain region; and
a second gate electrode including a second polysilicon layer formed on the second gate insulation layer and doped with second conductivity type impurities, a second amorphized metal barrier layer and a second refractory metal layer.

12. The semiconductor device of claim 10, wherein the first channel region is recessed in the semiconductor substrate.

13. A method of fabricating a semiconductor device comprising:
preparing a semiconductor substrate provided with a gate insulation layer thereon;
forming a polysilicon layer doped with impurities on the gate insulation layer, wherein the polysilicon layer has a first conductivity type;
forming a metal barrier layer on the polysilicon layer;
amorphizing a surface of the metal barrier layer;
forming a refractory metal layer on the amorphized surface of the metal barrier layer; and
forming a gate electrode having a first conductivity type transistor by sequentially patterning the refractory metal layer, the metal barrier layer with the amorphized surface, the polysilicon layer doped with impurities and the gate insulation layer.

14. The method of claim 13, wherein the first conductivity type is a P-type conductivity.

15. The method of claim 14, wherein forming the polysilicon layer includes:
forming the polysilicon layer doped with N-type impurities on an entire surface of the semiconductor substrate having the gate insulation layer thereon; and
implanting P-type impurities into a portion of the polysilicon layer doped with N-type impurities.

16. The method of claim 14, wherein forming the polysilicon layer doped with impurities includes:
doping a first portion of the polysilicon layer with first conductivity impurities; and
doping a second portion of the polysilicon layer with second conductivity type impurities.

17. The method of claim 16, wherein the first portion and the second portion are doped simultaneously.

18. The method of claim 16, further comprising forming another gate electrode having a second conductivity type transistor by sequentially patterning another refractory metal layer, another amorphized metal barrier layer, another polysilicon layer doped with the second conductivity impurities and another gate insulation layer,
wherein the another gate electrode is formed from the second portion of the polysilicon layer and simultaneously with forming the gate electrode for the first conductivity type transistor.

19. The method according to claim 13, wherein the amorphizing is performed by treating a surface of the refractory metal layer with plasma.

20. The method of claim 19, wherein the plasma is formed of a source selected from the group consisting of He, Ne, Ar, Kr, Xe and N₂.

21. The method of claim 13, wherein amorphizing the surface of the metal barrier layer includes forming an amorphous structure portion at an upper part thereof,
wherein the amorphous structure portion extends from the surface of the metal barrier layer to a depth into the metal barrier layer, further wherein a thickness of the amorphous structure portion is 50% or less of the total thickness of the metal barrier layer.
